(19) United States
(12) Patent Application Publication
(10) Pub. No.: US 2005/0265009 A1
(43) Pub. Date: Dec. 1, 2005

(54) Detecting short circuits and detecting component misplacement

(75) Inventors: Thomas Fussinger, Erkheim (DE); Dennis Thompson, Ulm (DE)

Correspondence Address: BANNER & WITCOFF, 1001 G STREET N W, SUITE 1100, WASHINGTON, DC, 20001, US

(73) Assignee: Nokia Corporation, ESPOO (FI)

(21) Appl. No.: 10/953,790

(22) Filed: Sep. 30, 2004

(30) Foreign Application Priority Data
Jun. 1, 2004 (GB) 0412179.4

(51) Int. Cl. H05K 7/06

(52) U.S. Cl. 361/777

(57) ABSTRACT

The invention provides an arrangement and method for detecting shorts between solder pads 31-34 in the production testing of circuit boards. The invention is particularly suitable for circuits driven by a constant current source or sink 6. By providing a conductor 101-103 between the solder pads, connected by a resistive path 11 to a source of potential 12, an additional current will flow through the resistive path to the solder pads if a short circuit exists in the region wherein the conductor is positioned. The additional current can be detected by applying a test probe in a circuit including the solder pads. The invention also provides an arrangement and method for detecting whether a polarity sensitive component 1 has been correctly connected to terminals 4, 5 on the circuit board. The component 1 can be a capacitor having one relatively wide positive terminal 2 and one relatively narrow negative terminal 3. The positive and negative terminals are intended to be connected to a positive and a negative connector respectively on the circuit board. Auxiliary pads 6a, 6b coupled to the positive connector 4 are provided juxtaposed with the negative connector 5 such that, if the capacitor is wrongly placed, the positive terminal 2 of the capacitor connects the negative connector 5 with the auxiliary connector 6a, 6b. Thus, the capacitor 1 is short-circuit and the misplacement can be detected by a suitable testing method.

This invention relates to an arrangement and to a method for detecting short circuits on a board. More specifically, but not exclusively, it relates to detecting shorts in a circuit on a Printed Wire Board wherein the circuit is driven by a constant current sink. Additionally, it relates to an arrangement on a board for receiving a polarity sensitive component, and to a method of testing if a component is wrongly connected to an arrangement.

During and after production of electronic circuit boards for use in for example radiotelephones, displays and various electronic gadgets, the components on the electronic circuit boards and the circuit connecting them need to be tested to detect faults in the components and also faults arising during the assembly. Typical faults include short circuits between solder pads created during soldering. If the short circuits are not detected, faulty products can be released for sale.

Hence, there is a demand for cost-effective detection of short circuits on Printed Wire Boards and similar. A conventional method of detecting short circuits comprises using a test equipment to detect the current flowing through one or more components of a circuit. If the circuit is driven by a voltage source, the resistance of the components limits the amount of current flowing through them. Thus, if a short-circuit allows current to take a different path and avoid the components, a current different to that expected may be detected and, thus, the short circuit can be detected.

An example of a circuit wherein a constant power source is beneficial is a circuit comprising a plurality of LEDs. Due to the nature of LEDs, they can easily be damaged by connecting them to a voltage source higher than its turn on voltage. A good LED driver circuit is, therefore, either a constant current sink or an approximation to a current sink made by connecting the LED in series with a suitable current limiting resistor and a voltage source. However, the conventional method of detecting shorts between LEDs may not work when the circuit is powered by a constant current sink.

The invention aims to ameliorate the problems discussed above.

According to the invention there is provided an arrangement comprising two adjacent solder pads on a surface of a board, and a conductor located between and non-contacting the solder pads, the conductor forming part of a path to a first source of potential.

Preferably the path is a resistive path, since this has certain advantages. However, the path could be a simple conductor connection to the first source of potential.

One of the solder pads can be connected to a constant current sink. Also one of the solder pads may be connected to a second source of potential, different from the first. The conductor may have an open circuit at one end. Thus, if there is a short between the two adjacent solder pads, there is also a short between the solder pad and the conductor, and the potential difference in the path will result in an additional current flowing through the short-circuited solder pad. Consequently, the current in a circuit comprising at least one of the two short-circuited solder pads will be different from the expected current, and the short-circuit can be detected. One end of the conductor can be an open circuit. One end of the same or another conductor can be a short circuit.

According to the invention there is also provided a method of testing an arrangement comprising two adjacent solder pads on a surface of a board, and a conductor located between and non-contacting the solder pads, the conductor forming part of a path to a first source of potential, the method comprising applying a testing potential to an electrical circuit including at least one of the solder pads so that the testing potential being different than the potential of the first source of potential, detecting a current resulting from applying the testing potential, and determining the existence of a short circuit based on the detected current.

Another example of a fault that may arise during manufacture of electronic goods includes a components connected wrongly. Most components can be tested before release of the product. However, some components may appear to be working properly at the testing stage but may stop working correctly at a later stage. One such example is a polarity sensitive capacitor used as a back up power source in a device. A conventional way of testing the correct placement of a capacitor comprises applying a voltage to a circuit including the capacitor in order to allow it to charge up and subsequently to check whether it has charged, i.e. if there is a potential difference present across it. However, a polarised capacitor connected the wrong way around could exhibit a voltage across it but eventually, during use, it could break down and stop functioning correctly. Thus, a method of testing if a polarity sensitive components are accurately connected is needed.

The invention aims to provide a solution.

According to another aspect of the invention, there is provided an arrangement on a board for receiving a polarity sensitive component having first and second terminals, the arrangement comprising a first connector intended to be connected to the first terminal, a second connector intended to be connected to the second terminal, and an auxiliary connector electrically coupled to the first connector and juxtaposed with the second connector so that, if the component is wrongly placed, the first terminal connects the second connector with the auxiliary connector.

The component may be a capacitor.

The first terminal preferably is wider than the second terminal. The first terminal may also be wider than the width of the second conductor and the auxiliary conductor combined. Thus, if the polarity sensitive component is placed in contact with the second conductor, it will also contact the auxiliary conductor so that a current can follow a path short-circuiting the component. This can allow the fault to be detected during production testing.

According to the invention there is also provided a method of testing if a polarity sensitive component, having first and second terminals, is wrongly connected to an arrangement on a board having a first connector intended to be connected to the first terminal, a second connector intended to be connected to the second terminal, and an auxiliary connector electrically coupled to the first connector and juxtaposed with the second connector so that, if the component is wrongly placed, the first terminal connects the second connector with the auxiliary connector, the method comprising applying a potential difference in a circuit comprising said first, second and auxiliary connectors, and measuring the potential difference across the polarity sensitive component, determining if the polarity sensitive component has been wrongly connected to the arrangement based on the detected potential difference.

Embodiments of the present inventions will now be described, by way of example, with reference to the accompanying drawings, in which:

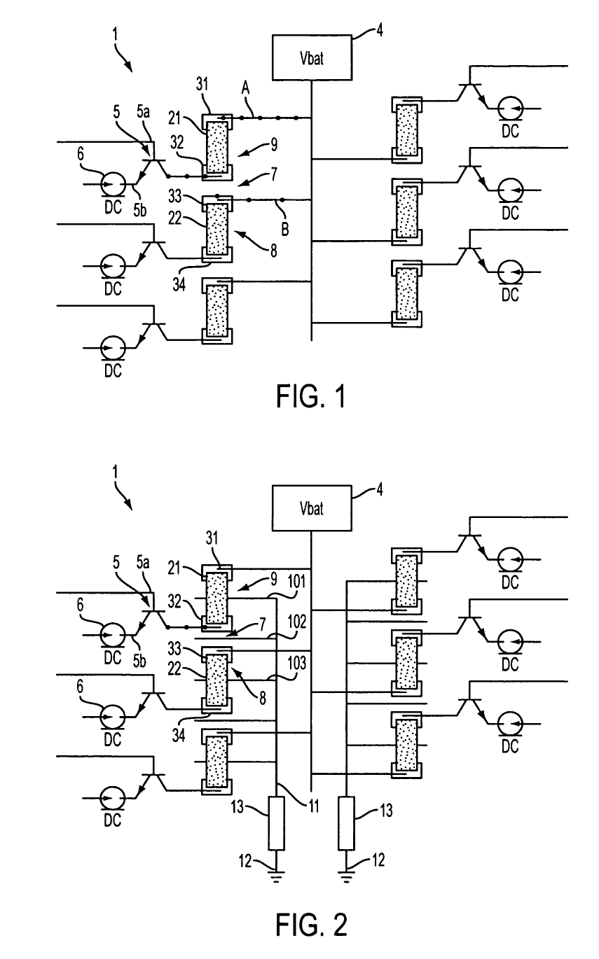

FIG. 1 is a schematic drawing of a circuit to be tested for short circuits;

FIG. 2 is a schematic drawing of the circuit of FIG. 1 and an arrangement according to the invention for detecting short circuits;

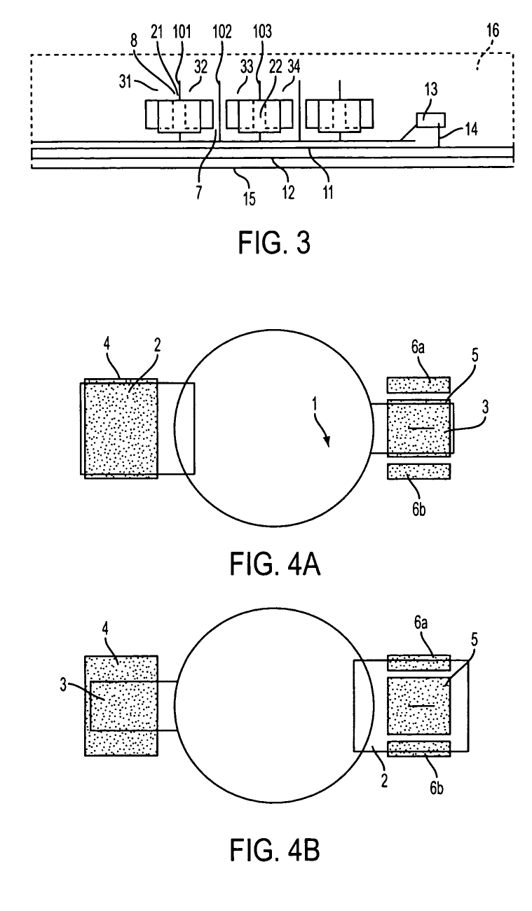

FIG. 3 shows how the arrangement of FIG. 2 is implemented on a Printed Wire Board (PWB);

FIG. 4a is a schematic drawing of a electronic component correctly connected and soldered to connectors on a board;

FIG. 4b is a schematic drawing of the electronic component wrongly connected to connectors on a board;

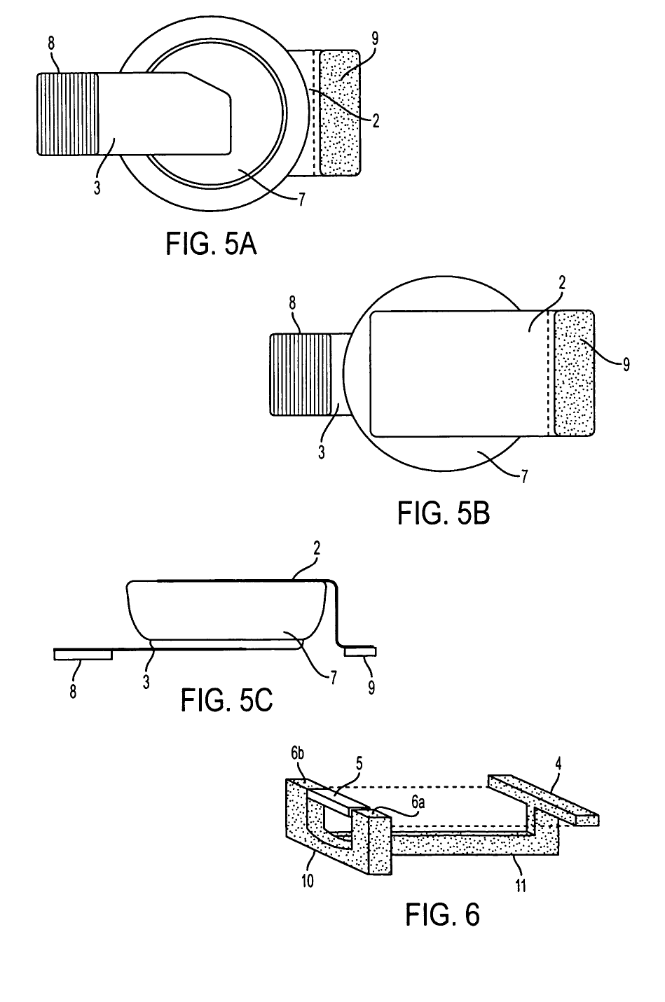

FIG. 5a to 5c illustrates the structure of the electronic component of FIGS. 4a and 4b;

FIG. 6 shows a perspective view of an arrangement on a board according to the invention.

FIG. 1 shows a circuit 1 comprising light emitting diodes (LED) 21, 22, each connected by way of a plurality of solder pads 31-34. LED 21 is soldered to solder pads 31 and 32 and LED 22 is soldered to solder pads 33 and 34. The LEDs 21, 22 are further connected in parallel to a battery 4 providing a source of potential in the circuit. Each LED 21, 22 is further connected to a respective switch 5, constituted by an npn transistor. A gate electrode 5a of the switch 5 is connected to a control circuit (not shown), and one other terminal of the switch 5a is connected to a constant current sink 6. Any two adjacent solder pads are separated by gaps 7, 8 or 9. Solder pads 31 and 32 are separated by gap 9, solder pads 32 and 33 are separated by gap 7 and solder pads 33 and 34 are separate by gap 8. The circuit, except the LEDs 21, 22, is printed on a Printed Wire Board (not shown).

In order to operate one of the LEDs, the switch 5 connected to the LEDs 21, 22 is closed by applying a voltage to its gate electrode 5a. When the switch is closed, electrons from the constant current sink 6 flows through the LED to switch it on.

In the production testing of the circuit 1 in FIG. 1, it is difficult to determine if there is a short circuit in the gaps 7 or 8. If a test probe is coupled to the circuit between the battery and the LED 21, the electrons flowing through solder pad 31 can be detected. If gaps 7 and 9 do not short circuit, the electrons will follow a path A, extending from solder pad 32, through the LED 21 and solder pad 31 to the battery 4. On the other hand, if gap 7 is short circuited, connecting the adjacent solder pads 32 and 33, the electrons will take path B extending from solder pad 32 to solder pad 33 and then to battery 4. However, since the LEDs 21, 22 are driven by a constant current sink 6, the current through path A and B is the same, so the short circuit cannot be detected.

FIG. 2 shows an arrangement according to one aspect of the invention. Reference numerals are retained from FIG. 1 for like elements. In FIG. 2, conductors 101-103 are connected in the regions between two adjacent solder pads. Conductors 101 and 103 are positioned underneath LEDs 21 and 22 respectively. Conductor 102 is positioned between solder pads 32 and 33. The conductors 101-103 are further connected through a resistive path 11 to a source of potential 12. The source of potential 12 is at ground potential. The resistive path 11 includes a resistor 13. If there is a short circuit between any two adjacent solder pads 31-34, at least one of the tracks 101-103 is in electrical contact with at least one of the solder pads and, due to the potential difference between the ground track 11 and the solder pad, a current flows in the resistive path 11. This results in a different current being detected by the testing apparatus connected to the test probe. Although the path 11 is described as being resistive, the path could instead be a simple track connecting directly to ground potential 12.

FIG. 3 is a plan view of a surface of a printed wire board 16, wherein the solid line 15 shows one side edge of the printed wire board. Reference numerals are retained from FIG. 1 and from FIG. 2 for like elements. Track 12 in FIG. 3 is connected to ground potential. The LEDs 21, 22 are soldered to the solder pads 31, 32, 33 and 34, as described with reference to FIG. 1 and FIG. 2. The edges of the solder pads covered by the upper surface of the LEDs are shown in broken lines. Moreover, conductors 101-103 comprise tracks between the solder pads 31-34, which tracks are connected together and to a resistor 13. The resistor 13 is connected to ground potential 12 by a track 14. The conductors 101, 103 in the gaps 8 and 9 are positioned on the surface of the board inbetween the solder pads and underneath the respective LED 21 and 22. The conductor 102 in gap 7 is positioned on the surface of the board, in between the LEDs 21 and 22. Each LED 21 and 22 is connected to a constant current sink and to a source of potential (not shown in FIG. 3). The gaps 7, 8 and 9 between the solder pads are relatively narrow, significantly smaller than the width of the solder pads. Accordingly, during soldering, a short may occasionally be formed between the solder pads across the gaps 7 and 8.

Testing is carried out as described above in relation to FIG. 2, namely the circuit is powered and a test probe (not shown), applying a testing potential which is different to the potential supplied by the battery 4, is connected to the circuit between a battery and an LED 21, 22. If there is a short circuit between one of the solder pads 31-34 and one of the conductors 101-103, the current flowing through the test probe will be different to the current that would flow if there were no short circuit. Test apparatus including the test probe may make a short circuit determination in any suitable way, as will be appreciated by the skilled person.

It should be noted that the invention is not limited to the circuits of FIG. 2 and FIG. 3. The production testing of any circuit driven by a constant or generally constant current sink or source may be improved by the invention. Moreover, the solder pads do not have to be used for connecting LEDs, but could be used for various other electronic component in a circuit. Moreover, the number of conductors 101-103 connected to the resistive path can be varied in order to adapt the arrangement according to the circuit to be tested. The resistive path 11 does not need to be connected to ground potential, but could instead be connected to any suitable source of potential. Moreover, the conductors 101-103 do not have to end in the regions between the solder pads, and thereby provide an open circuit. They can be connected to an additional source of potential in a resistive or non-resistive path. Moreover, one or both of the resistors shown in FIGS. 1 and 2 can be removed from the circuit.

FIG. 4a shows an electronic component 1, having a positive terminal 2 and a negative terminal 3 connected respectively to a positive component connector pad 4 and a negative component connector pad 5 on a board (not shown). The positive terminal 2 is intended to be connected to the positive connector pad 4 and the negative terminal 3 is intended to be connected to the negative connector pad 5. In FIG. 4a the connectors 4, 5 are in the form of conducting pads. The positive terminal 2 has a larger width than the negative terminal 3. Similarly, the positive pad 4 has a larger width than the negative pad 5. The terminals 2, 3 of component 1 are soldered onto the pads 3, 4. The electronic component 1 is polarity sensitive. Thus, if it is not connected the right way around, it may not work properly. Here, the electronic component 1 is a capacitor. The component 1 will hereinafter be referred to as a capacitor but will be understood not to be limited to a capacitor. The capacitor 1 may be used as a back-up source of power in a circuit. A conventional method of testing if a capacitor is connected properly is to charge it up and then measure the potential difference between its terminals. In a conventional arrangement for receiving the capacitor, the capacitor would become charged to some extent and could pass the test even if it was wrongly connected.

FIG. 4b shows the capacitor 1 wrongly connected. However, according to the invention, there are provided two auxiliary connectors 6a and 6b in the form of pads. Pads 6a and 6b are electrically coupled to each other and to the positive pad 4. The connections are shown in FIG. 6 described below. They are located such that when the large positive terminal 2 of the capacitor 1 is connected to the small negative pad 5, the positive terminal 2 will also connect to at least one of the auxiliary pads 6a and 6b. Thus, the capacitor 1 is shorted and will not be charged when a potential is applied to the pads 3 and 4. Consequently, after a voltage, which normally would charge the capacitor 1, has been applied, the voltage across the capacitor would be significantly lower than expected and the circuit would fail the production test. The capacitor 1 could then be realigned or replaced.

FIG. 5a shows a plan view of the lower surface of the capacitor 1, i.e. the surface closest to the circuit board. The negative terminal 3 is generally rectangular, and is attached to the main body 7 of the capacitor 1. The negative terminal 3 includes an area 8 with solder plating, for soldering the terminal 3 to the pad 5 of the circuit board. FIG. 5b shows a plan view of the top surface of the capacitor 1. The positive terminal 2 is generally rectangular and has a larger width and larger area than the negative terminal 3. Here, the width of the positive terminal is 3 mm and the width of the negative terminal is 2 mm. The positive terminal 2 is attached to the main body 7 of the capacitor 1. The positive terminal 2 moreover comprises a region 9 comprising solder plating for soldering the terminal to the pad 4 of the circuit board, although the solder is located on the opposite side of the terminal shown in the Figure. The positive terminal 2 is bent perpendicular to the surface of the battery as shown in the side view of the battery in FIG. 5c. Thus, the regions 8 and 9 of the first and second terminals are in the same plane and can be soldered to the pads 4, 5 on the circuit board.

One embodiment of the connecter pads 4, 5, 6a, 6b is shown in FIG. 6. Reference numerals are retained from FIGS. 4 and 5 for like elements. The auxiliary pads 6a, 6b are connected directly to the positive pad 4 by way of a U-shaped conductor 10, which connects the pads 6a and 6b, and a conductor 11, below the surface of the circuit board, leading to the positive pad from the conductor 10. The plane of the surface of the circuit board is illustrated by the broken line.

The manner in which the auxiliary conductors 6a, 6b and the positive conductor 4 are connected together can be varied. In an alternative embodiment, the auxiliary conductors 6a, 6b and the positive conductor 4 can be connected to a common track of a printed wire board. Moreover, the shape, size and number of auxiliary pads can be varied without deviating from the invention as claimed in the claims.

1. An arrangement comprising
two adjacent solder pads on a surface of a board, and
a conductor located between and non-contacting the solder pads, the conductor forming part of a path to a first source of potential.

2. The arrangement of claim 1 wherein one or more of the solder pads is connected to a generally constant current sink or source.

3. The arrangement of claim 1 or 2 wherein one of the solder pads is connected to a second source of potential, different from the first source of potential.

4. The arrangement of claim 1, wherein the path includes a resistor.

5. The arrangement of claim 1, wherein one end of the conductor is an open circuit.

6. The arrangement of claim 1, wherein the distance between said two adjacent solder pads is such that there is a significant probability of a short being created thereacross during soldering.

7. The arrangement of claim 6, wherein the solder pads are larger than the distance between the solder pads.

8. The arrangement of claim 6, wherein the solder pads are smaller than the distance between the solder pads.

9. The arrangement of claim 1 wherein the surface of the board supports plural solder pads and conductor arrangements.

10. A radiotelephone including the board of claim 9.

11. A method of testing an arrangement comprising two adjacent solder pads on a surface of a board, and a conductor located between and non-contacting the solder pads, the conductor forming part of a path to a first source of potential, the method comprising
applying a testing potential to an electrical circuit including at least one of the solder pads, the testing potential being different to the potential of the first source of potential,
detecting a current resulting from applying the testing potential, and
determining the existence of a short circuit based on the detected current.

12. The method of claim 11 wherein the detecting step comprises determining if the detected current deviates from an expected current.

13. An arrangement on a board for receiving a polarity sensitive component having first and second terminals, the arrangement comprising:
a first connector intended to be connected to the first terminal,
a second connector intended to be connected to the second terminal, and
an auxiliary connector electrically coupled to the first connector and juxtaposed with the second connector so that, if the component is wrongly placed, the first terminal connects the second connector with the auxiliary connector.

14. The arrangement of claim 13, wherein the operative area of the first connector is about the same as that of the second and auxiliary connectors combined.

15. The arrangement of claims 13 or 14, wherein the auxiliary connector is directly connected to the first connector.

16. The arrangement of claim 13 arranged to receive a polarity sensitive capacitor.

17. The arrangement of claim 13 arranged to receive a polarity sensitive back up power source.

18. The arrangement of claim 13, wherein the first terminal is wider than the second terminal.

19. The arrangement of claim 13 wherein the first terminal is wider than the second connector.

20. A method of testing if a polarity sensitive component, having first and second terminals, is wrongly connected to an arrangement on a board having a first connector intended to be connected to the first terminal, a second connector intended to be connected to the second terminal, and an auxiliary connector electrically coupled to the first connector and juxtaposed with the second connector so that, if the component is wrongly placed, the first terminal connects the second connector with the auxiliary connector, the method comprising:
applying a potential difference in a circuit comprising said first, second and auxiliary connectors, and
detecting a potential difference across the polarity sensitive component,
determining if the polarity sensitive component has been wrongly connected to the arrangement based on the detected potential difference.
